(19) United States
(12) Patent Application Publication
(10) Pub. No.: US 2016/0197095 A1
(43) Pub. Date: Jul. 7, 2016

(54) SEMICONDUCTOR DEVICE

(71) Applicant: Panasonic Intellectual Property Management Co., Ltd., Osaka (JP)

(72) Inventors: Ichiro YAMANE, Kanagawa (JP); Masaki INOUE, Osaka (JP)

(21) Appl. No.: 15/066,776

(22) Filed: Mar. 10, 2016

Related U.S. Application Data
(63) Continuation of application No. PCT/JP2014/002467, filed on May 9, 2014.

(30) Foreign Application Priority Data
Sep. 11, 2013 (JP) 2013-188101

(51) Int. Cl. H01L 27/12; H01L 29/73; G05F 1/46; H01L 49/02; H01L 29/866; H01L 29/06; H01L 29/861

(52) U.S. Cl. CPC H01L 27/1203; H01L 29/0649; H01L 29/73; H01L 29/861; H01L 28/20; H01L 29/866; G05F 1/468

(57) ABSTRACT

Disclosed herein is a technique for reducing, in an analog circuit that needs trimming adjustment in a semiconductor device, a variation to be caused in the characteristic of the analog circuit while the circuit is kept in stock for a long time after having been packaged or subjected to a reflow process. An analog circuit including a trimming mechanism for output adjustment is formed on a buried oxide film in a semiconductor substrate. A trench structure is provided to surround at least one of elements constituting this analog circuit, and includes an insulating oxide layer having a hollow structure.

### CROSS-REFERENCE TO RELATED APPLICATIONS

This is a continuation of International Application No. PCT/JP2014/002467 filed on May 9, 2014, which claims priority to Japanese Patent Application No. 2013-188101 filed on Sep. 11, 2013. The entire disclosures of these applications are hereby incorporated by reference.

### BACKGROUND

The present disclosure relates to a semiconductor device including an analog circuit with a trimming mechanism for adjustment.

A regulator circuit or a measurement circuit for a battery or a sensor is required to have their precision increased. To meet this need, the silicon-on-insulator (SOI) technology is applied to transistors that form a reference voltage generator functioning as a principal portion of these circuits, thereby attempting to improve the temperature characteristic with their precision increased.

A conventional reference voltage generator that adopts the SOI technology will now be described.

FIG. 12 shows an exemplary bandgap reference circuit that is one of reference voltage generators (see Japanese Unexamined Patent Publication No. 2008-288290).

An operational amplifier 66 has its output connected in parallel to a circuit in which a resistor 63 and an NPN bipolar transistor 61 are connected together in series, and to a circuit in which the resistor 64, an NPN bipolar transistor 62, and another resistor 65 are connected together in series. The resistor 63 is connected to the collector and base of the NPN bipolar transistor 61, and the resistor 64 is connected to the collector and base of the NPN bipolar transistor 62. The emitter of the NPN bipolar transistor 61 is grounded, and the emitter of the NPN bipolar transistor 62 is connected to the resistor 65, the other terminal of which is grounded.

The NPN bipolar transistor 61 and the NPN bipolar transistor 62 are configured to have a ratio of 1:K. The K value, the resistance values of the resistors 63, 64, and 65, the circuit configuration of the operational amplifier, and other parameters are optimized according to the load and supply voltage of the bandgap reference circuit and process specifications. The bandgap reference circuit generates a constant voltage that does not depend on the ambient temperature, cancels the temperature characteristic of the P-N diode junction, and outputs the bandgap voltage of silicon (about 1.2 V) through an output terminal Vref. The optimization of the circuit parameters allows for reducing a variation in output voltage in response to a change in the ambient temperature. Thus, the bandgap reference circuit is mounted on a semiconductor integrated circuit device to generate a reference voltage for a constant voltage generator or a constant current generator.

As each of the NPN bipolar transistors, a semiconductor element having the structure illustrated in FIG. 13 is used. According to the structure shown in FIG. 13, the NPN bipolar transistor, an exemplary semiconductor element, is completely isolated from adjacent elements by a buried oxide film 13 and an insulating oxide layer 10. The isolated element includes an n-type layer 22 in which a p-type layer 24 is provided, and a heavily-doped p-type layer 23 is formed in the p-type layer 24 so as to function as a base. A heavily-doped n-type layer 25 is further formed in the p-type layer 24 so as to function as an emitter, and a heavily-doped n-type layer 21 is formed in the n-type layer 22 so as to function as a collector. The reference numeral 15 denotes a shallow trench isolation (STI) structure. The complete isolation of this element reduces significantly the amount of current leaking to a substrate 44, thus attempting to improve the temperature characteristic with the precision increased.

### SUMMARY

However, if an analog circuit that needs trimming adjustment is kept in stock for a long time after having been packaged or subjected to a reflow process, its characteristic tends to vary too significantly and too sensibly for the analog circuit to satisfy the target specification simply by improving the temperature characteristic of a reference voltage generator. Specifically, the characteristics of a transistor, a diode, and a resistor vary due to the application of external stress to a semiconductor chip, thereby making it difficult for the analog circuit to satisfy the reference voltage standard required. This point will be described below.

FIG. 14A shows a semiconductor device that has not been encapsulated with resin yet. No external stress is applied at all to a semiconductor chip 51 at this point in time.

FIG. 14B shows the semiconductor device that has been encapsulated with a resin 53. The semiconductor chip 51 is mounted on a leadframe 52, and is subjected to stress from the resin 53 in such a direction as to compress the chip. In this case, in the structure in FIG. 13, the external stress ST is applied as it is to the bipolar transistor. Therefore, a bandgap reference circuit built in the semiconductor chip 51 has its reference voltage Vref shifted by the strain resulting from the stress from the resin 53.

FIG. 14C shows, in an exaggerated form, the semiconductor device that has just undergone a reflow process. The resin 53 is further cured and compressed under the heat applied by the reflow process. Therefore, the bandgap reference circuit built in the semiconductor chip 51 has its reference voltage Vref further shifted by the strain resulting from the stress applied from the resin 53 during the reflow process.

FIG. 14D shows the semiconductor device that has been left at room temperature for ten years since the semiconductor device underwent the reflow process. The longer the semiconductor device is left, the smaller degree of curing of the resin 53 that was once cured through the reflow process. As a result, the state of the resin 53 becomes closer and closer to the state shown in FIG. 14B. In this case, in the structure in FIG. 13, a decreased external stress ST is applied as it is to the bipolar transistor. Therefore, the bandgap reference circuit built in the semiconductor chip 51 allows its reference voltage Vref to recover the value immediately after resin encapsulation, because the strain is relaxed as the stress from the resin 53 decreases.

To solve these problems, according to an aspect of the present disclosure, a semiconductor device includes: a semiconductor substrate in which a buried oxide film is formed; and an analog circuit formed on the buried oxide film in the semiconductor substrate, and including a trimming mechanism for adjustment. A trench structure is formed to surround at least one of elements constituting the analog circuit, and includes an insulating oxide layer having a hollow structure.

According to the present disclosure, a trench structure is formed to surround an element forming part of the analog circuit, and includes an insulating oxide layer having a hollow structure. This thus allows for reducing a variation in the characteristic of the analog circuit under the influence of external stress.

If the element surrounded with the trench structure forms part of a reference voltage generator, a shift in the reference potential due to the application of external stress may be reduced. If the element surrounded with the trench structure forms part of a current mirror circuit, a variation in the amount of current flowing due to the application of the external stress resulting from a mismatch may be reduced. If the element surrounded with the trench structure forms part of a differential amplifier circuit, a variation in its characteristic due to the application of the external stress resulting from a mismatch may be reduced.

### BRIEF DESCRIPTION OF THE DRAWINGS

FIG. 1 shows a circuit configuration for a regulator circuit according to an embodiment.

FIG. 2 shows an exemplary circuit configuration for a bandgap reference circuit according to a first embodiment.

FIG. 3 illustrates an exemplary structure of a transistor according to the first embodiment.

FIG. 4 illustrates an exemplary structure of a resistor according to the first embodiment.

FIG. 5 shows an exemplary circuit configuration for a reference voltage generator including Zener diodes according to a second embodiment.

FIG. 6 illustrates an exemplary structure of a diode according to the second embodiment.

FIG. 7 shows another exemplary layout of trench structures.

FIG. 8 shows still another exemplary layout of trench structures.

FIG. 9 shows yet another exemplary layout of trench structures.

FIG. 10 shows a further exemplary layout of trench structures.

FIG. 11 shows a still further exemplary layout of trench structures.

FIG. 12 shows a bandgap reference circuit according to a conventional example.

FIG. 13 shows the structure of a transistor according to a conventional example.

FIGS. 14A-14D illustrate how stress is applied from a resin to a semiconductor chip.

### DETAILED DESCRIPTION

### First Embodiment

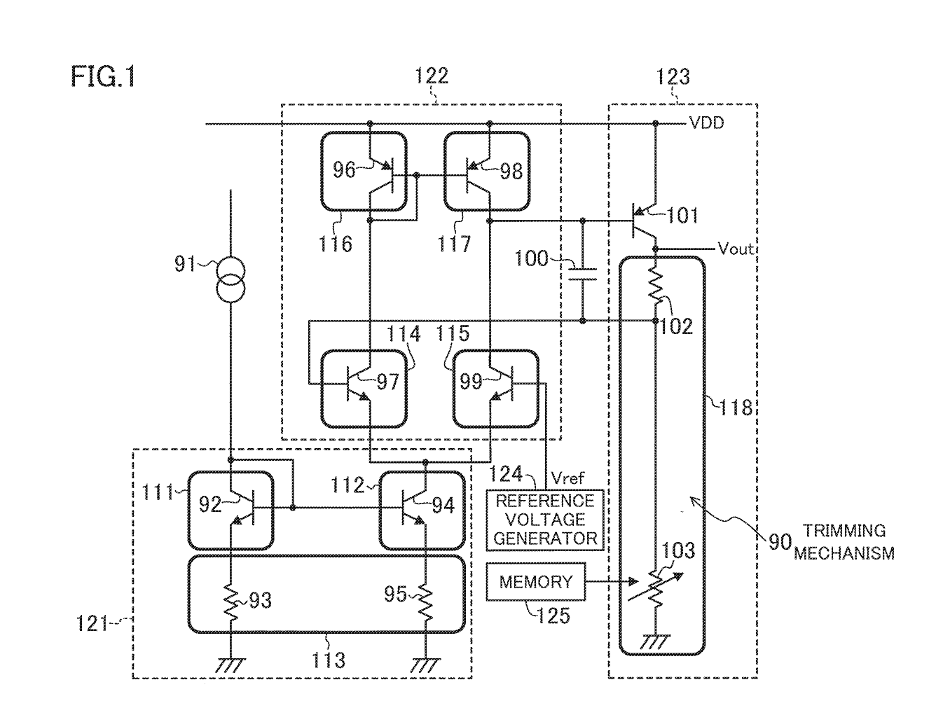

FIG. 1 shows an exemplary regulator circuit according to an embodiment. The regulator circuit shown in FIG. 1 is an exemplary analog circuit formed on a buried oxide film in a semiconductor substrate.

The regulator circuit is comprised of a reference voltage generator 124, a current source 91, a current mirror circuit 121, a differential amplifier circuit 122, a follower circuit 123, and a memory 125. The follower circuit 123 includes a trimming mechanism 90 comprised of a resistor 102 and a trimmable variable resistor 103, and the trimming mechanism 90 has the function of adjusting the output Vout of this regulator circuit.

The output of the current source 91 is connected or coupled to the collector and base of an NPN bipolar transistor 92 of the current mirror circuit 121, and the emitter of the NPN bipolar transistor 92 is grounded via a resistor 93. The base of the NPN bipolar transistor 92 is connected or coupled to the base of an NPN bipolar transistor 94, and the emitter of the NPN bipolar transistor 94 is grounded via a resistor 95.

The collector of the NPN bipolar transistor 94 is connected or coupled to the respective emitters of NPN bipolar transistors 97, 99 of the differential amplifier circuit 122. The collector of the NPN bipolar transistor 97 is connected or coupled to the base and collector of the PNP bipolar transistor 96. The emitter of the PNP bipolar transistor 96 is connected or coupled to a power supply VDD. The collector of the NPN bipolar transistor 99 is connected or coupled to the collector of the PNP bipolar transistor 98. The emitter of the PNP bipolar transistor 98 is connected or coupled to the power supply VDD. The base of the NPN bipolar transistor 99 is connected or coupled to the output terminal Vref of the reference voltage generator 124.

The collector of the NPN bipolar transistor 99 is connected also to the base of the PNP bipolar transistor 101 of the follower circuit 123. The emitter of the PNP bipolar transistor 101 is connected or coupled to the power supply VDD. The collector of the PNP bipolar transistor 101 is connected or coupled to one terminal of the resistor 102, the other terminal of which is connected or coupled to one terminal of the variable resistor 103. The other terminal of the variable resistor 103 is grounded. The other terminal of the resistor 102 is connected also to the base of the NPN bipolar transistor 97 and a phase compensation capacitor 100. The other terminal of the capacitor 100 is connected or coupled to the base of the PNP bipolar transistor 101.

The variable resistor 103 is capable of trimming its resistance value using the memory 125.

The NPN bipolar transistor 92 is surrounded by a trench structure 111. In the same manner, the NPN bipolar transistor 94 is surrounded by a trench structure 112, the NPN bipolar transistor 97 by a trench structure 114, and the NPN bipolar transistor 99 by a trench structure 115. In addition, the PNP bipolar transistor 96 is surrounded by a trench structure 116. In the same manner, the PNP bipolar transistor 98 is surrounded by a trench structure 117. The PNP bipolar transistor 101 may or may not be surrounded by a trench structure.

The resistors 93 and 95 are surrounded by a trench structure 113. In the same manner, the resistor 102 and the variable resistor 103 are surrounded by a trench structure 118.

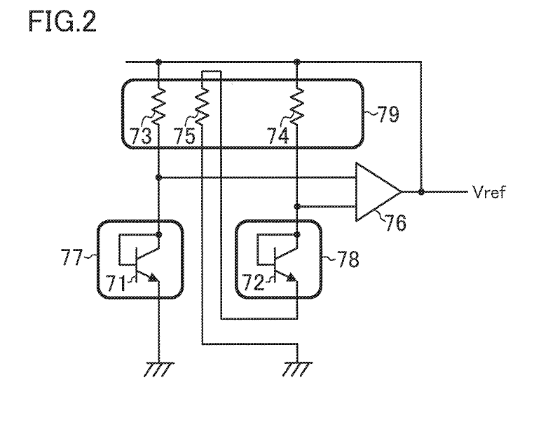

FIG. 2 shows an exemplary bandgap reference circuit as an example of the reference voltage generator 124.

An operational amplifier 76 has its output connected in parallel to a circuit in which a resistor 73 and an NPN bipolar transistor 71 are connected together in series, and a circuit in which a resistor 74, an NPN bipolar transistor 72, and a resistor 75 are connected together in series. The resistor 73 is connected or coupled to the collector and base of the NPN bipolar transistor 71. The resistor 74 is connected or coupled to the collector and base of the NPN bipolar transistor 72. The emitter of the NPN bipolar transistor 71 is grounded. The emitter of the NPN bipolar transistor 72 is connected or coupled to the resistor 75, the other terminal of which is grounded. The NPN bipolar transistor 71 is surrounded by a trench structure 77. In the same manner, the NPN bipolar transistor 72 is surrounded by a trench structure 78. In addition, the resistors 73, 74, and 75 are surrounded by a trench structure 79.

The NPN bipolar transistor 71 and the NPN bipolar transistor 72 are configured to have a ratio of 1:K. The K value, the resistance values of the resistors 73, 74, and 75, the circuit configuration of the operational amplifier, and other parameters are optimized according to the load and supply voltage of the bandgap reference circuit and process specifications. The bandgap reference circuit generates a constant voltage that does not depend on the ambient temperature, cancels the temperature characteristic of the P-N diode junction, and outputs a bandgap voltage of silicon (of about 1.2 V) to the output terminal Vref. The optimization of the circuit parameters allows for reducing a variation in output voltage in response to a change in the ambient temperature. Thus, the bandgap reference circuit is mounted on a semiconductor integrated circuit device to generate a reference voltage.

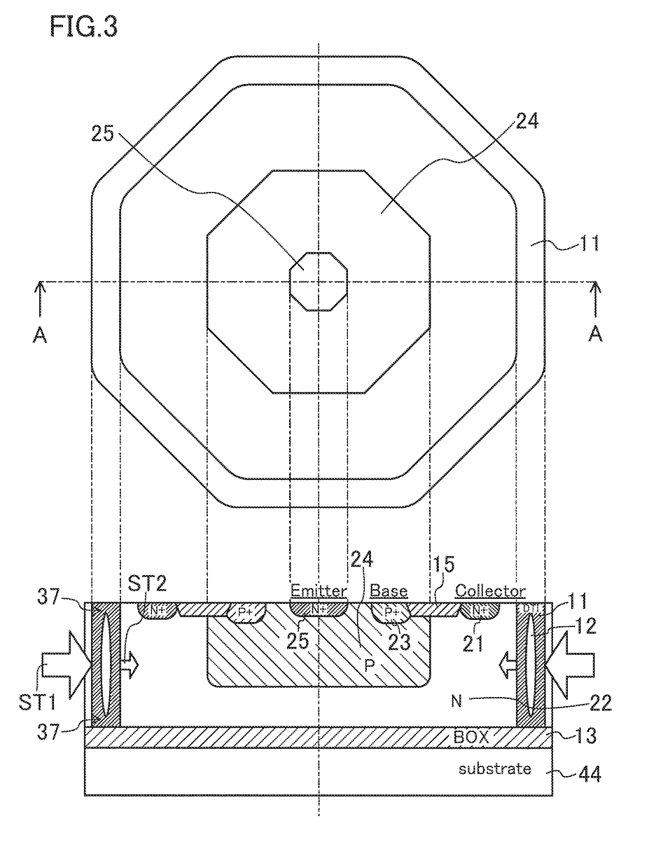

As the NPN bipolar transistors that are exemplary elements, semiconductor elements, each having the structure illustrated in FIG. 3, may be used. The upper half of FIG. 3 is a plan view, and the lower half thereof is a cross-sectional view taken along the plane A-A in the upper half. According to the structure in FIG. 3, the NPN bipolar transistor, an exemplary semiconductor element, is isolated from adjacent elements by a buried oxide film 13 and an insulating oxide layer 11 functioning as a trench structure. The insulating oxide layer 11 has a hollow structure 12 in its central portion. The hollow structure 12 is filled with any of a vacuum, a gas, or a material having a different composition from the semiconductor substrate and a low Young's modulus. There is an n-type layer 22 in the isolated element. A p-type layer 24 is provided in the n-type layer 22. A heavily-doped p-type layer 23 is further formed in the p-type layer 24 so as to function as a base. A heavily-doped n-type layer 25 is further formed in the p-type layer 24 so as to function as an emitter. A heavily-doped n-type layer 21 is further provided in the n-type layer 22 so as to function as a collector. The reference character 15 denotes a shallow trench isolation (STI) structure.

As viewed in plan, the insulating oxide layer 11 has a polygonal shape, so does the p-type layer 24. The heavily-doped n-type layer 25 functioning as the emitter also has a polygonal shape. The closer to a circle this shape is, the more stabilized the characteristic of the element becomes. However, because of various constraints on the actual layout, a square, hexagonal, or octagonal shape is selected.

Note that the PNP bipolar transistors may be configured such that the n-type and p-type layers in the structure in FIG. 3 have their conductivity types changed with each other.

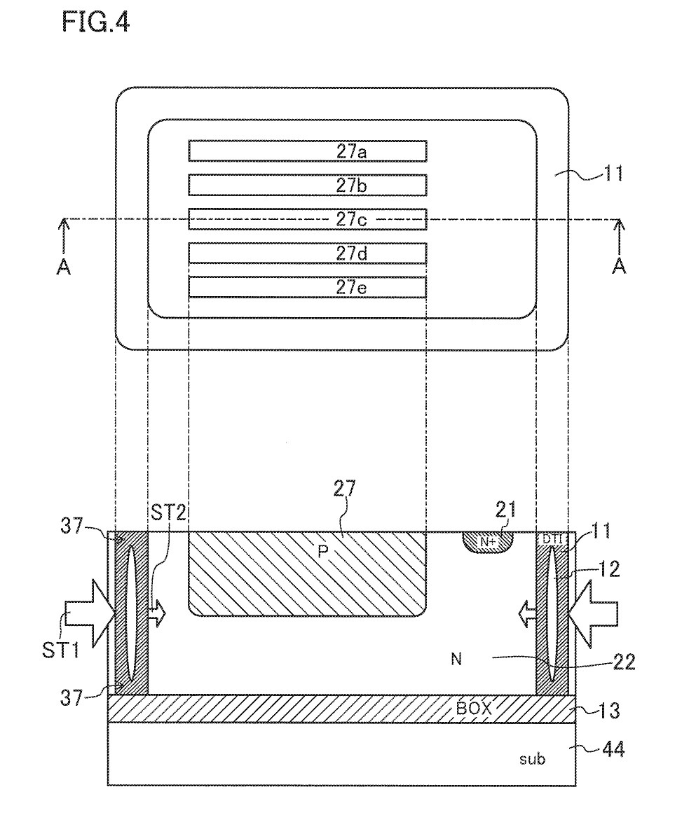

As the resistors that are exemplary elements, semiconductor elements each having the structure illustrated in FIG. 4 may be used. The upper half of FIG. 4 is a plan view, and the lower half thereof is a cross-sectional view taken along the plane A-A in the upper half. According to the structure in FIG. 4, the resistor, an exemplary element, is isolated from adjacent elements by a buried oxide film 13 and an insulating oxide layer 11 functioning as a trench structure. The insulating oxide layer 11 has a hollow structure 12 in its central portion. The hollow structure 12 may be filled with any of a vacuum, a gas, or a material having a different composition from the semiconductor substrate and a low Young's modulus. There is an n-type layer 22 in the isolated element. Five p-type layers 27, namely, p-type layers 27a, 27b, 27c, 27d, and 27e, are formed in the n-type layer 22 so as to function as resistors. The p-type layers 27b, 27d, and 27c are used as the resistors 73, 74, and 75, respectively, and the p-type layers 27a and 27e are dummy resistors.

The operation of the regulator circuit in FIG. 1 will now be described. The current source 91 supplies a constant current to the differential amplifier circuit 122 via the current mirror circuit 121. In this case, the NPN bipolar transistors 92, resistors 93, NPN bipolar transistors 94, and resistors 95 are arranged such that the ratio of the number of NPN bipolar transistor 92-resistor 93 pairs to that of NPN bipolar transistor 94-resistor 95 pairs is 1:N. Actually, however, there is a mismatch between these two groups, and the current ratio between them becomes different from 1:N.

The differential amplifier circuit 122 compares, with the reference voltage Vref, a voltage obtained by dividing the output Vout of the follower circuit 123 using the resistor 102 and the variable resistor 103. Then, the differential amplifier circuit 122 drives the PNP bipolar transistor 101 of the follower circuit 123 such that the reference voltage Vref has the same potential as the voltage obtained by dividing the output Vout. Actually, however, there is a mismatch between the NPN bipolar transistors 97 and 99 and between the PNP bipolar transistors 96 and 98, and thus these two voltages do not have the same potential.

In addition, the reference voltage Vref that is the output of the reference voltage circuit 124 is not constant due to a process induced variation.

Thus, to allow the output Vout to fall within the standardized voltage range, the value of the variable resistor 103 of the trimming mechanism 90 is adjusted to compensate for the shift arising from the dispersion in reference voltage Vref between individual products, the mismatch between the bipolar transistors, and the mismatch between the resistors.

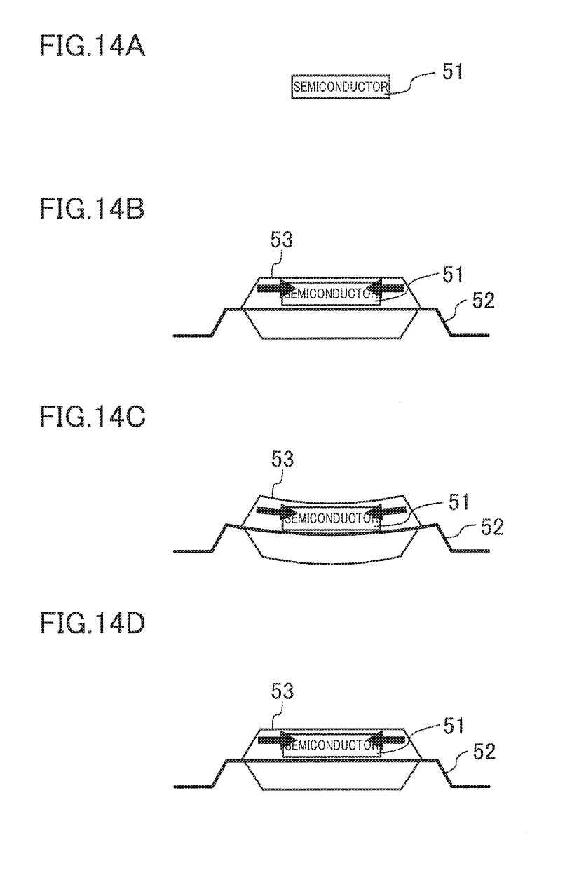

FIG. 14A shows a semiconductor device that has not been encapsulated with resin yet. No external stress is applied at all to a semiconductor chip 51 at this point in time. A probe test is usually conducted in this state, the value of the variable resistor 103 of the trimming mechanism 90 is adjusted such that the output Vout of the regulator circuit becomes equal to a specified value, and the adjusted value is stored, as a trimming value, in the memory 125.

FIG. 14B shows the semiconductor device that has been encapsulated with a resin 53. A semiconductor chip 51 is mounted on a leadframe 52, and is subjected to stress from the resin 53 in such a direction as to compress the chip. Therefore, in the regulator circuit in FIG. 1 built in the semiconductor chip 51, the bipolar transistor structure illustrated in FIG. 3 is subjected to the external stress ST1 as the stress applied from the resin 53. However, the resultant strain concentrates at top and bottom portions 37 of the insulating layer 11 owing to the presence of the hollow structure 12. This thus allows for relieving the stress ST2 applied to the transistor, and eventually reducing a variation in transistor characteristic. Likewise, the resistor and variable resistor illustrated in FIG. 4 are also subjected to the external stress ST1. However, the resultant strain concentrates at top and bottom portions 37 of the insulating layer 11 owing to the presence of the hollow structure 12. This thus allows for relieving the stress ST2 applied to the resistor and the variable resistor, and eventually reducing a variation in the resistor characteristic. As a result, variations in the characteristics of the reference voltage generator 124, current mirror circuit 121, differential amplifier circuit 122, and follower circuit 123, and their mismatches are reduced, thus allowing for maintaining the reference voltage Vout output from the regulator circuit without changing the trimming value stored in the memory 125 during the probe test.

FIG. 14C shows, in an exaggerated form, the semiconductor device that has just undergone a reflow process. The resin 53 is further cured and compressed under the heat applied by the reflow process. Therefore, in the regulator circuit in FIG. 1 built in the semiconductor chip 51, the bipolar transistor structure illustrated in FIG. 3 is subjected to the external stress ST1 as the stress applied from the resin 53. However, the resultant strain concentrates at the top and bottom portions 37 of the insulating layer 11 owing to the presence of the hollow structure 12. This thus allows for relieving the stress ST2 applied to the transistor, and eventually reducing a variation in the transistor characteristic. Likewise, the resistor and variable resistor illustrated in FIG. 4 are also subjected to the external stress ST1. However, the resultant strain concentrates at the top and bottom portions 37 of the insulating layer 11 owing to the presence of the hollow structure 12. This thus allows for relieving the stress ST2 applied to the resistor and the variable resistor, and eventually reducing a variation in the resistor characteristic. As a result, variations in the characteristics of the reference voltage generator 124, current mirror circuit 121, differential amplifier circuit 122, and follower circuit 123, and their mismatches are reduced, thus allowing for maintaining the reference voltage Vout output from the regulator circuit even after the reflow process without changing the trimming value stored in the memory 125 during the probe test.

FIG. 14D shows the semiconductor device that has been left at room temperature for ten years since the semiconductor device underwent the reflow process. The longer the semiconductor device is left, the smaller degree of curing of the resin 53 that was once cured through the reflow process. As a result, the state of the resin 53 becomes closer and closer to the state shown in FIG. 14B. Therefore, in the regulator circuit in FIG. 1 built in the semiconductor chip 51, the external stress ST1 applied to the bipolar transistor structure illustrated in FIG. 3 is removed as the stress applied from the resin 53 is removed. However, the removal of the strain concentrates at the top and bottom portions 37 of the insulating layer 11 owing to the presence of the hollow structure 12. This thus allows for lessening the removal of the stress ST2 applied to the transistor, and eventually reducing a variation in the transistor characteristic. Likewise, the external stress ST1 applied to the resistor and variable resistor illustrated in FIG. 4 is also removed. However, the removal of the strain concentrates at the top and bottom portions 37 of the insulating layer 11 owing to the presence of the hollow structure 12. This thus allows for lessening the removal of the stress ST2 applied to the resistor and variable resistor, and eventually reducing a variation in the resistor characteristic. As a result, variations in the characteristics of the reference voltage generator 124, current mirror circuit 121, differential amplifier circuit 122, and follower circuit 123, and their mismatches are reduced, thus allowing for maintaining the reference voltage Vout output from the regulator circuit, even if the semiconductor device is left at room temperature for ten years, without changing the trimming value stored in the memory 125.

Note that such a structure itself, in which a hollow insulating oxide layer is provided on a buried oxide film, is already known from Japanese Unexamined Patent Publication No. 2006-49828. This patent document, however, discloses how much the relief of the stress contributes to forming a transistor as designed if the stress is relieved at a stage in which no interconnect layer has been formed yet on an SOI substrate during the manufacturing process of the transistor. That is to say, nobody has ever disclosed how effective the removal of the external stress is for the transistor being fabricated if the stress is removed after the transistor or the interconnect layer has been formed.

### Second Embodiment

FIG. 1 shows an exemplary regulator circuit according to a second embodiment. The regulator circuit shown in FIG. 1 is an exemplary analog circuit formed on a buried oxide film in a semiconductor substrate.

The regulator circuit includes a reference voltage generator 124, a current source 91, a current mirror circuit 121, a differential amplifier circuit 122, a follower circuit 123, and a memory 125. The follower circuit 123 includes a trimming mechanism 90 comprised of a resistor 102 and a trimmable variable resistor 103. The trimming mechanism 90 has the function of adjusting the output Vout of the regulator circuit.

FIG. 5 shows an exemplary reference voltage generator 124 including Zener diodes. The reference voltage generator in FIG. 5 generates a constant voltage that does not depend on the ambient temperature, cancels the temperature characteristic of the diode junction, and outputs a reference voltage through the output terminal Vref.

The output of a current source 81 is connected in series to a Zener diode 82 and a Zener diode 83. The anode of the Zener diode 82 is connected or coupled to the current source 81, and the cathode of the Zener diode 82 is connected or coupled to the cathode of the Zener diode 83. The anode of the Zener diode 83 is grounded. The Zener diode 82 is surrounded by a trench structure 84, and the Zener diode 83 by a trench structure 85.

The Zener diode 83 uses its breakdown voltage as a reference voltage. If the voltage is 5 V or less, the Zener diode 83 generally has a positive temperature characteristic. Thus, the Zener diode 83 is connected in series in a forward direction to the Zener diode 82 having a negative temperature characteristic to correct the temperature characteristic of the Zener diode 83. Note that the Zener diode 82 may be replaced with a general diode.

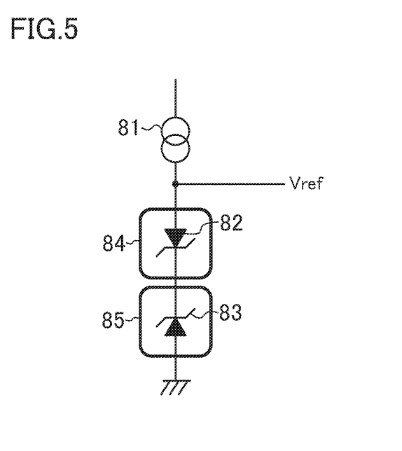

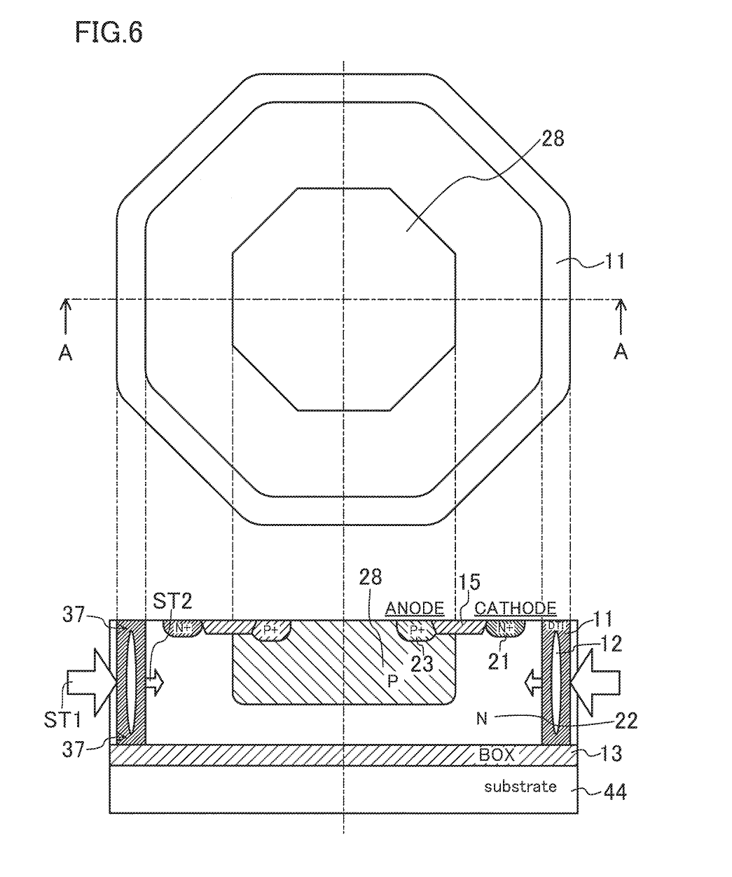

As the Zener diodes that are exemplary elements, semiconductor elements each having the structure illustrated in FIG. 6 may be used. The upper half of FIG. 6 is a plan view, and the lower half thereof is a cross-sectional view taken along the plane A-A in the upper half. The Zener diode, an exemplary semiconductor element, is completely isolated from adjacent elements by a buried oxide film 13 and an insulating oxide layer 11 functioning as a trench structure. The insulating oxide layer 11 has a hollow structure 12 in its central portion. The hollow structure 12 may be filled with any of a vacuum, a gas, or a material having a different composition from the semiconductor substrate and a low Young's modulus. There is an n-type layer 22 in the isolated element. A p-type layer 28 is provided in the n-type layer 22. A heavily-doped p-type layer 23 is further formed in the p-type layer 28 so as to function as an anode. A heavily-doped n-type layer 21 is further provided in the n-type layer 22 so as to function as a cathode. The reference numeral 15 denotes a shallow trench isolation (STI) structure.

As viewed in plan, the insulating oxide layer 11 has a polygonal shape, so does the p-type layer 28. The closer to a circle this shape is, the more stabilized the characteristic of the element becomes. However, because of various constraints on the actual layout, a square, hexagonal, or octagonal shape is selected.

FIG. 14A shows a semiconductor device that has not been encapsulated with resin yet. No external stress is applied at all to a semiconductor chip 51 at this point in time. A probe test is usually conducted in this state, the value of the variable resistor 103 of the trimming mechanism is adjusted such that the output Vout of the regulator circuit becomes equal to a specified value, and the adjusted value is stored, as a trimming value, in the memory 125. Note that the output voltage may be trimmed in a test process after assembly.

FIG. 14B shows the semiconductor device that has been encapsulated with a resin 53. The semiconductor chip 51 is mounted on a leadframe 52, and is subjected to the stress from the resin 53 in such a direction as to compress the chip. Therefore, in the regulator circuit in FIG. 1 built in the semiconductor chip 51, the diode structure illustrated in FIG. 6 is subjected to external stress ST1 as the stress applied from the resin 53. However, the resultant strain concentrates on the top and bottom portions 37 of the insulating layer 11 owing to the presence of the hollow structure 12. This thus allows for relieving the stress ST2 applied to the diode, and eventually reducing a variation in the diode characteristic. The bipolar transistors and resistors are the same as their counterparts of the first embodiment. As a result, variations in the characteristics of the reference voltage generator 124, current mirror circuit 121, differential amplifier circuit 122, and follower circuit 123, and their mismatches are reduced, thus allowing for maintaining the reference voltage Vout output from the regulator circuit without changing the trimming value stored in the memory 125 during the probe test.

FIG. 14C shows, in an exaggerated form, the semiconductor device that has just undergone a reflow process. The resin 53 is further cured and compressed under the heat applied by the reflow process. Therefore, in the regulator circuit in FIG. 1 built in the semiconductor chip 51, the diode structure illustrated in FIG. 6 is subjected to the external stress ST1 as the stress applied from the resin 53. However, the resultant strain concentrates on the top and bottom portions 37 of the insulating layer 11 owing to the presence of the hollow structure 12. This thus allows for relieving the stress ST2 applied to the diode, and eventually reducing a variation in the diode characteristic. The bipolar transistors and the resistors are the same as their counterparts of the first embodiment. As a result, variations in the characteristics of the reference voltage generator 124, current mirror circuit 121, differential amplifier circuit 122, and follower circuit 123, and their mismatches are reduced, thus allowing for maintaining the reference voltage Vout output from the regulator circuit even after the reflow process without changing the trimming value stored in the memory 125.

FIG. 14D shows the semiconductor device that has been left at room temperature for ten years since the semiconductor device underwent the reflow process. The longer the semiconductor device is left, the smaller degree of curing of the resin 53 that was once cured through the reflow process. As a result, the state of the resin 53 becomes closer and closer to the state shown in FIG. 14B. Therefore, in the regulator circuit in FIG. 1 built in the semiconductor chip 51, the external stress ST1 applied to the diode structure illustrated in FIG. 6 is removed as the stress applied from the resin 53 is removed. However, the removal of the strain concentrates at the top and bottom portions 37 of the insulating layer 11 owing to the presence of the hollow structure 12. This thus allows for lessening the removal of the stress ST2 applied to the diode, and eventually reducing a variation in the diode characteristic. The bipolar transistors and the resistors are the same as their counterparts of the first embodiment. As a result, variations in the characteristics of the reference voltage generator 124, current mirror circuit 121, differential amplifier circuit 122, and follower circuit 123, and their mismatches are reduced, thus allowing for maintaining the reference voltage Vout output from the regulator circuit, even if the semiconductor device is left at room temperature for ten years, without changing the trimming value stored in the memory 125.

(Other Configurations)

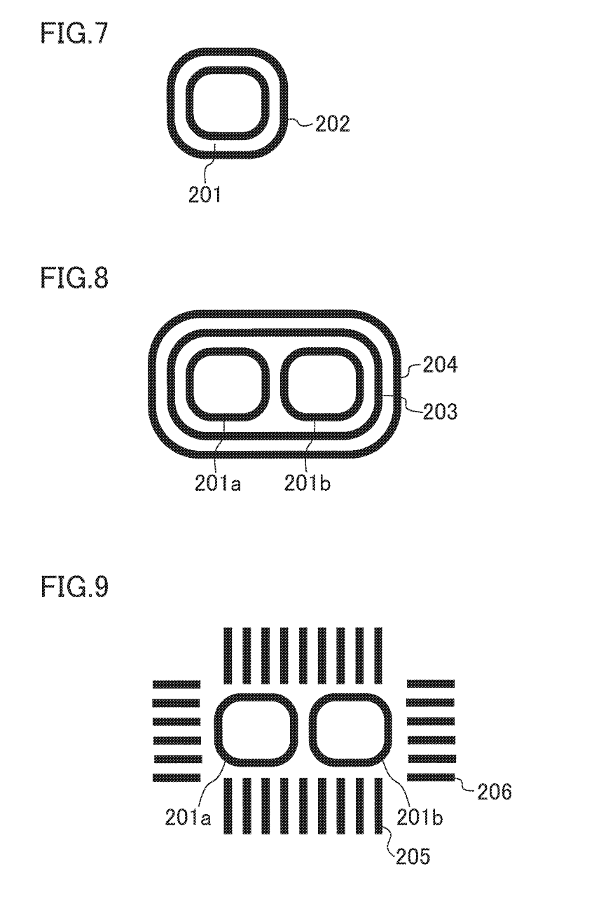

FIGS. 7-11 are plan views illustrating other exemplary layouts of trench structures.

In FIG. 7, the reference numeral 201 denotes the trench structure described for the first and second embodiments, which has a hollow structure in its central portion. The hollow structure is filled with any of a vacuum, a gas, or a material having a different composition from a semiconductor substrate and a low Young's modulus. The stress applied to the element is further reduced by providing an additional trench structure 202 surrounding the trench structure 201. Note that a double trench structure is formed in the example shown in FIG. 7, but may be replaced with any other multi-trench structure.

In FIG. 8, the reference numerals 201a and 201b denote the trench structures described for the first and second embodiments, which each have a hollow structure in its central portion. The hollow structure is filled with any of a vacuum, a gas, or a material having a different composition from a semiconductor substrate and a low Young's modulus. The stress applied to a group of elements is further reduced by providing additional trench structures 203 and 204 surrounding the group of elements, each of which is already surrounded with the trench structure 201a, 201b. Note that a triple trench structure is formed in the example shown in FIG. 8, but may be replaced with any other multi-trench structure.

In FIGS. 9 and 10, the reference numerals 201a and 201b denote the trench structures described for the first and second embodiments, which each have a hollow structure in its central portion. The hollow structure is filled with any of a vacuum, a gas, or a material having a different composition from a semiconductor substrate and a low Young's modulus. The stress applied to a group of elements is further reduced by providing additional trench structures 205 and 206 or 207 and 208 surrounding the group of the elements, each of which is already surrounded with the trench structure 201a, 201b. In FIG. 9, the trench structures 205 and 206 have a rod shape. In FIG. 10, on the other hand, the trench structures 207 and 208 have a rectangular shape having rounded corners. However, the shapes of the trench structures to provide may have any arbitrary shape.

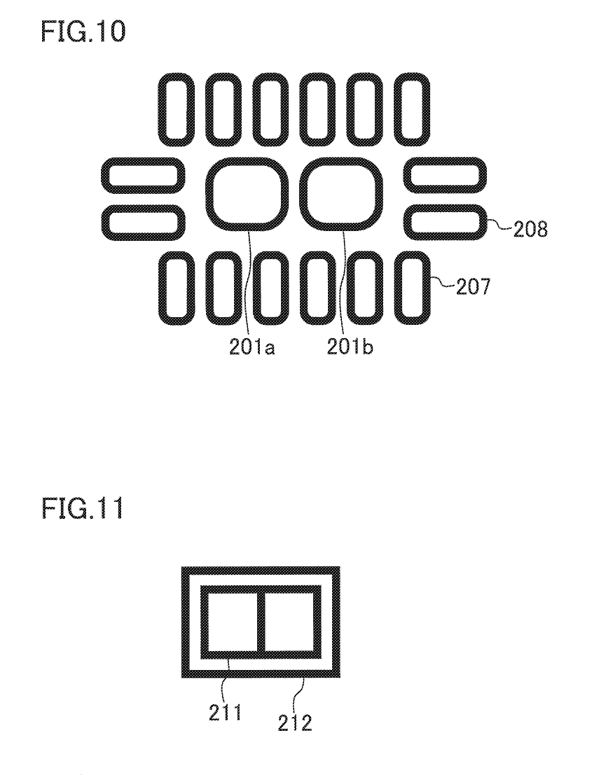

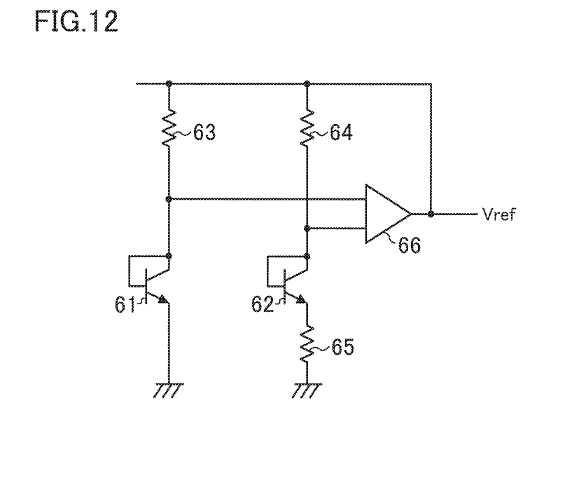

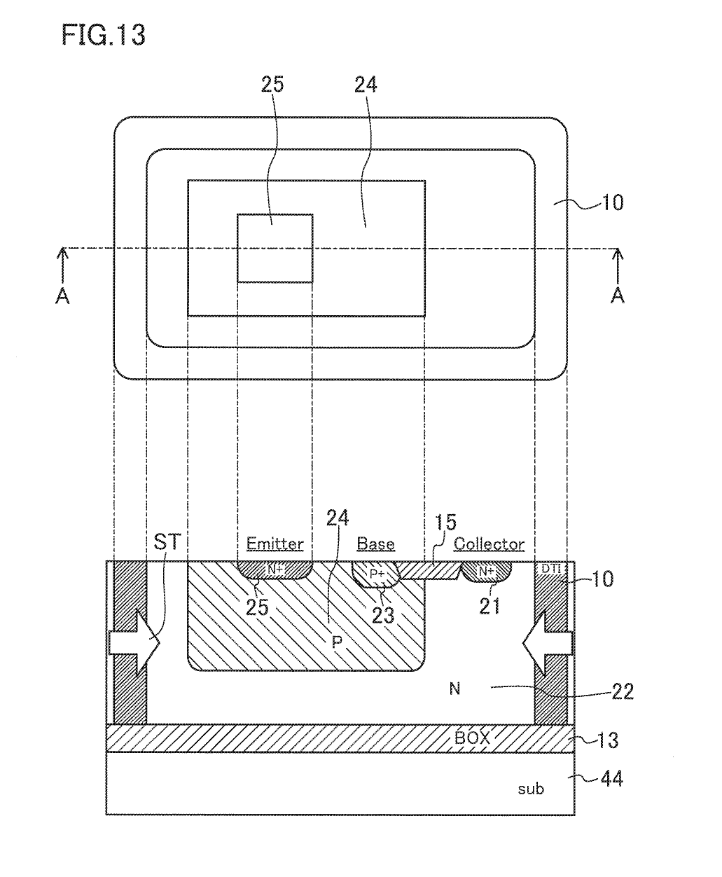

In FIG. 11, the reference numeral 211 denotes a trench structure having a branch at its midway point, which has a hollow structure in its central portion. The hollow structure is filled with any of a vacuum, a gas, or a material having a different composition from a semiconductor substrate and a low Young's modulus. The stress applied to a group of elements is further reduced by providing an additional trench structure 212 surrounding the group of the elements, which are already surrounded with the trench structure 211.

The present disclosure is applicable to a wide variety of products, such as electric vehicles, hybrid vehicles, mobile electronic devices, and meter instruments, all of which require measurement of batteries or sensors.

What is claimed is:

1. A semiconductor device comprising:
a semiconductor substrate in which a buried oxide film is formed; and
an analog circuit formed on the buried oxide film in the semiconductor substrate, and including a trimming mechanism for adjustment, wherein
a trench structure is formed to surround at least one of elements constituting the analog circuit, and includes an insulating oxide layer having a hollow structure.

2. The semiconductor device of claim 1, wherein
the hollow structure of the insulating oxide layer is filled with a material having a different composition from the semiconductor substrate.

3. The semiconductor device of claim 1, wherein
the element is a transistor.

4. The semiconductor device of claim 1, wherein
the element is a diode.

5. The semiconductor device of claim 1, wherein
the element is a resistor.

6. The semiconductor device of claim 1, wherein
the element forms part of a reference voltage generator.

7. The semiconductor device of claim 1, wherein
the element forms part of a current mirror circuit.

8. The semiconductor device of claim 1, wherein
the element forms part of a differential amplifier circuit.

9. The semiconductor device of claim 1, wherein
at least one second trench structure is provided outside the trench structure.

10. The semiconductor device of claim 6, wherein
the reference voltage generator is a bandgap reference circuit including the trimming mechanism.

11. The semiconductor device of claim 6, wherein
the reference voltage generator includes a Zener diode.

12. The semiconductor device of claim 10, wherein
a need for trimming an output voltage after reflow is eliminated.

13. The semiconductor device of claim 11, wherein
a need for trimming an output voltage after reflow is eliminated.

14. The semiconductor device of claim 12, wherein
the output voltage is trimmed in a probe test or in a test process after assembly.
